(19) United States
(12) Patent Application Publication
(10) Pub. No.: US 2025/0194324 A1
(43) Pub. Date: Jun. 12, 2025

(54) LIGHT EMITTING ELEMENT

(71) Applicant: NICHIA CORPORATION, Anan-shi (JP)

(72) Inventor: Ryohei KOBAYASHI, Tokushima-shi (JP)

(73) Assignee: NICHIA CORPORATION, Anan-shi (JP)

(21) Appl. No.: 18/971,806

(22) Filed: Dec. 6, 2024

(30) Foreign Application Priority Data
Dec. 11, 2023 (JP) 2023-208830

(51) Int. Cl. H10H 29/14; H10H 29/80

(52) U.S. Cl. CPC H10H 29/14; H10H 29/8321; H10H 29/842; H10H 29/882

(57) ABSTRACT

A light emitting element includes: a semiconductor stack structure including: a first p-type semiconductor layer, a first active layer disposed on the first p-type semiconductor layer, a first n-type semiconductor layer disposed on the first active layer, an intermediate layer disposed on the first n-type semiconductor layer, a second p-type semiconductor layer disposed on the intermediate layer, a second active layer disposed on the second p-type semiconductor layer, and a second n-type semiconductor layer disposed on the second active layer, wherein: a plurality of first openings are continuously located in the first p-type semiconductor layer, the first active layer, and the first n-type semiconductor layer, and a plurality of second openings are continuously located in the first p-type semiconductor layer, the first active layer, the first n-type semiconductor layer, the intermediate layer, the second p-type semiconductor layer, the second active layer, and the second n-type semiconductor layer.

### CROSS-REFERENCE TO RELATED APPLICATIONS

The present application claims priority under 35 U.S.C. § 119 to Japanese Patent Application No. 2023-208830, filed Dec. 11, 2023, the contents of which is hereby incorporated by reference in its entirety.

### BACKGROUND

### 1. Technical Field

An embodiment of the present invention relates to a light emitting element.

### 2. Description of Related Art

U.S. Patent Publication No. 2009/0001389 discloses a structure in which a first LED including a green light emitting first active region and a second LED including a blue light emitting second active region are stacked via a tunnel junction.

### SUMMARY

An object of certain embodiments of the invention is to provide a light emitting element in which the emission of a first active layer and the emission of a second active layer can be individually controlled.

A light emitting element according to one embodiment of the present invention comprises a semiconductor stack structure, a first electrode, a second electrode, a third electrode, first wiring, second wiring, and third wiring. The semiconductor stack structure has a first p-type semiconductor layer, a first active layer, a first n-type semiconductor layer, an intermediate layer, a second p-type semiconductor layer, a second active layer, and a second n-type semiconductor layer. The first active layer is disposed on the first p-type semiconductor layer. The first n-type semiconductor layer is disposed on the first active layer. The intermediate layer is disposed on the first n-type semiconductor layer. The second p-type semiconductor layer is disposed on the intermediate layer. The second active layer is disposed on the second p-type semiconductor layer. The second n-type semiconductor layer is disposed on the second active layer. The semiconductor stack structure has a plurality of first openings and a plurality of second openings. The first openings are continuously provided in the first p-type semiconductor layer, the first active layer, and the first n-type semiconductor layer. The second openings are continuously provided in the first p-type semiconductor layer, the first active layer, the first n-type semiconductor layer, the intermediate layer, the second p-type semiconductor layer, the second active layer, and the second n-type semiconductor layer. The first electrode is located apart from the semiconductor stack structure in a plan view. The first electrode is electrically connected to the first p-type semiconductor layer. The second electrode is electrically connected to the second n-type semiconductor layer. The third electrode is electrically connected to the first n-type semiconductor layer. The first wiring is disposed under the semiconductor stack structure. The first wiring electrically connects the first electrode and the first p-type semiconductor layer. The second wiring is positioned in the second openings. The second wiring electrically connects the second electrode and the second n-type semiconductor layer. The third wiring is positioned in the first openings. The third wiring electrically connects the third electrode and the first n-type semiconductor layer.

A light emitting element according to another embodiment of the present invention comprises a semiconductor stack structure, a first electrode, a second electrode, a third electrode, first wiring, second wiring, and third wiring. The semiconductor stack structure has a first p-type semiconductor layer, a first active layer, a first n-type semiconductor layer, an intermediate layer, a second p-type semiconductor layer, a second active layer, and a second n-type semiconductor layer. The first active layer is disposed on the first p-type semiconductor layer. The first n-type semiconductor layer is disposed on the first active layer. The intermediate layer is disposed on the first n-type semiconductor layer. The second p-type semiconductor layer is disposed on the intermediate layer. The second active layer is disposed on the second p-type semiconductor layer. The second n-type semiconductor layer is disposed on the second active layer. The semiconductor stack structure has a plurality of first openings and a plurality of second openings. The first openings are continuously provided in the first p-type semiconductor layer, the first active layer, and the first n-type semiconductor layer. The second openings are continuously provided in the first p-type semiconductor layer, the first active layer, the first n-type semiconductor layer, the intermediate layer, the second p-type semiconductor layer, the second active layer, and the second n-type semiconductor layer. The first electrode is located apart from the semiconductor stack structure in a plan view. The first electrode is electrically connected to the first p-type semiconductor layer. The second electrode is electrically connected to the first n-type semiconductor layer. The third electrode is electrically connected to the second n-type semiconductor layer. The first wiring is disposed under the semiconductor stack structure. The first wiring electrically connects the first electrode and the first p-type semiconductor layer. The second wiring is positioned in the first openings. The second wiring electrically connects the second electrode and the first n-type semiconductor layer. The third wiring is positioned in the second openings. The third wiring electrically connects the third electrode and the second n-type semiconductor layer.

Embodiments of the present invention can provide a light emitting element in which the emission of a first active layer and the emission of a second active layer can be individually controlled.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a plan view of a light emitting element according to a first embodiment.

FIG. 2 is a cross-sectional view of the light emitting element according to the first embodiment.

FIG. 3 is a cross-sectional view of the electric current path in a first emission state of the light emitting element according to the first embodiment.

FIG. 4 is a cross-sectional view of the electric current path in a second emission state of the light emitting element according to the first embodiment.

FIG. 5 is a cross-sectional view of the electric current path in a third emission state of the light emitting element according to the first embodiment.

FIG. 6 is a plan view of a light emitting element which is a variation of the first embodiment.

FIG. 7 is a plan view of a light emitting element according to a second embodiment.

FIG. 8 is a cross-sectional view of the light emitting element according to the second embodiment.

FIG. 9 is a cross-sectional view of the electric current path in a first emission state of the light emitting element according to the second embodiment.

FIG. 10 is a cross-sectional view of the electric current path in a second emission state of the light emitting element according to the second embodiment.

FIG. 11 is a cross-sectional view of the electric current path in a third emission state of the light emitting element according to the second embodiment.

FIG. 12 is a plan view of a light emitting element which is a variation of the second

### DETAILED DESCRIPTION

Embodiments of the present invention will be explained below with reference to the accompanying drawings.

The drawings are schematic and conceptual. Consequently, the relationship between the thickness and the width of each part, the size ratio of members, and the like are not necessarily identical with those of an actual product. Even when the same portion is shown, the size or ratio might differ depending on the drawing.

In the present specification and drawings, similar elements already described using previously referenced drawings will be denoted with the same reference numerals, and a detailed description of such element is omitted as appropriate.

In the description below, an XYZ orthogonal coordinate system is employed for explaining the arrangements and configurations of the constituents. The X axis, Y axis, and Z axis are orthogonal to one another. The direction in which the X axis extends is designated as “X direction,” the direction in which the Y axis extends is designated as “Y direction,” and the direction in which the Z axis extends is designated as “Z direction.” In order to make the explanation easily understood, the Z direction pointed by the arrow is occasionally referred to as upward, and the opposite direction downward, but these expressions are irrespective of the direction of gravity. A “plan view” refers to a view when viewing an object in the direction along Z direction.

### First Embodiment

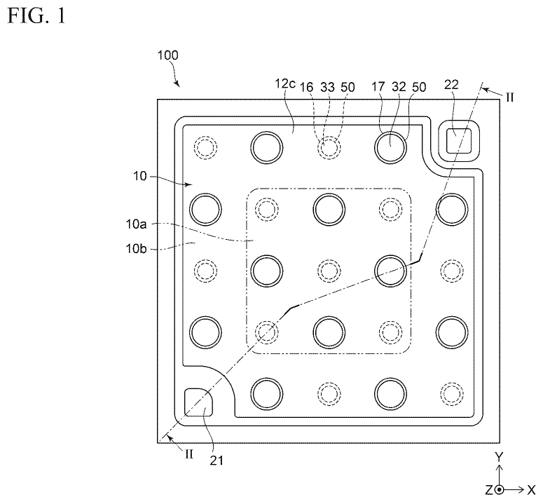

FIG. 1 is a plan view of a light emitting element according to a first embodiment.

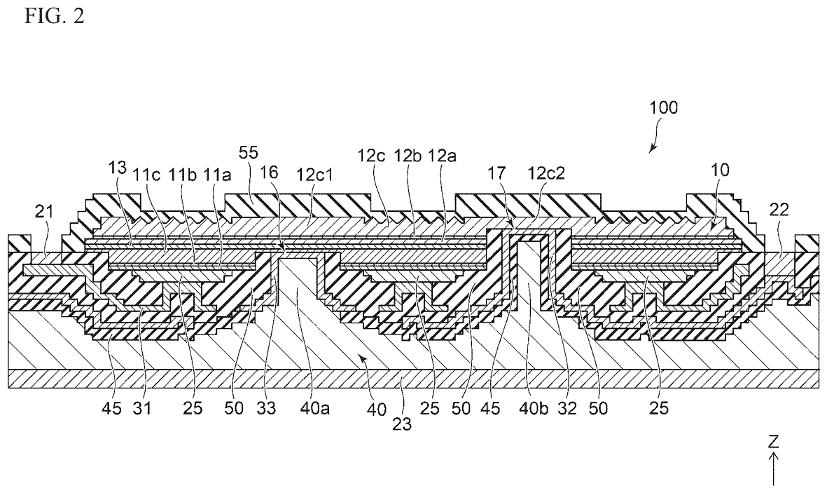

FIG. 2 is a cross-sectional view of the light emitting element according to the first

FIG. 2 is a cross section taken along line II-II in FIG. 1.

As shown in FIG. 1 and FIG. 2, the light emitting element 100 according to the first embodiment includes a semiconductor stack structure 10, a first electrode 21, a second electrode 22, a third electrode 23, first wiring 31, second wiring 32, and third wiring 33. As shown in FIG. 1, the shape of the light emitting element 100 in the plan view is a quadrangle. In the case in which the light emitting element 100 is quadrangular in the plan view, each side of the quadrangle is, for example, 50 μm to 2000 μm in length.

The semiconductor stack structure 10 has a first p-type semiconductor layer 11a, a first active layer 11b, a first n-type semiconductor layer 11c, an intermediate layer 13, a second p-type semiconductor layer 12a, a second active layer 12b, and a second n-type semiconductor layer 12c.

The first p-type semiconductor layer 11a is positioned as the lowermost part of the semiconductor stack structure 10. The first active layer 11b is disposed on the first p-type semiconductor layer 11a. The first n-type semiconductor layer 11c is disposed on the first active layer 11b. The intermediate layer 13 is disposed on the first n-type semiconductor layer 11c. The second p-type semiconductor layer 12a is disposed on the intermediate layer 13. The second active layer 12b is disposed on the second p-type semiconductor layer 12a. The second n-type semiconductor layer 12c is disposed on the second active layer 12b.

The first p-type semiconductor layer 11a, the first active layer 11b, the first n-type semiconductor layer 11c, the intermediate layer 13, the second p-type semiconductor layer 12a, the second active layer 12b, and the second n-type semiconductor layer 12c are each made of a nitride semiconductor, for example. In the present specification, the term “nitride semiconductor” includes all compositions obtained by varying the composition ratio x and y within their ranges in the chemical formula InₓAl_{y}Ga_{1-x-y}N (0≤x≤1, 0≤y≤1, x+y≤1). Moreover, those further containing a group V element in addition to nitrogen (N), and those further containing various elements added for controlling various physical properties such as conductivity type are also included in the term “nitride semiconductor.”

The first n-type semiconductor layer 11c and the second n-type semiconductor layer 12c contain, for example, Si (silicon) as an n-type impurity. The first p-type semiconductor layer 11a and the second p-type semiconductor layer 12a contain, for example, Mg (magnesium) as a p-type impurity. The first active layer 11b and the second active layer 12b are emission layers that emit light, and have a MQW (multiple quantum well) structure which includes multiple barrier layers and multiple well layers, for example. The peak wavelength of the light emitted by the first active layer 11b may be the same as or different from the peak wavelength of the light emitted by the second active layer 12b.

The intermediate layer 13 includes at least one of a p-type semiconductor layer having a higher p-type impurity concentration than that of the second p-type semiconductor layer 12a and an n-type semiconductor layer having a higher n-type impurity concentration than that of the first n-type semiconductor layer 11c. The intermediate layer 13 functions as a tunnel junction layer, for example.

The semiconductor stack structure 10 has multiple first openings 16 and multiple second openings 17. The first openings 16 are provided continuously in the first p-type semiconductor layer 11a, the first active layer 11b, and the first n-type semiconductor layer 11c. The first openings 16 are holes that go through the first p-type semiconductor layer 11a and the first active layer 11b before reaching the first n-type semiconductor layer 11c in the Z direction. The first openings 16 do not go through the first n-type semiconductor layer 11c. The second openings 17 are provided continuously in the first p-type semiconductor layer 11a, the first active layer 11b, the first n-type semiconductor layer 11c, the intermediate layer 13, the second p-type semiconductor layer 12a, the second active layer 12b, and the second n-type semiconductor layer 12c. The second openings 17 are holes that go through the first p-type semiconductor layer 11a, the first active layer 11b, the first n-type semiconductor layer 11c, the intermediate layer 13, the second p-type semiconductor layer 12a, and the second active layer 12b before reaching the second n-type semiconductor layer 12c in the Z direction. The second openings 17 do not go through the second n-type semiconductor layer 12c.

In the light emitting element 100, the shape of each of the first openings 16 and the second openings 17 in a plan view is a perfect circle. The shape of each of the first openings 16 and the second openings 17 in a plan view may be an ellipse, polygon, or the like.

The first electrode 21 is electrically connected to the first p-type semiconductor layer 11a. The first electrode 21 is positioned apart from the semiconductor stack structure 10 in a plan view. The first electrode 21 does not overlap the semiconductor stack structure 10 in the Z direction.

The second electrode 22 is electrically connected to the second n-type semiconductor layer 12c. The second electrode 22 is positioned apart from the semiconductor stack structure 10 in a plan view. The second electrode 22 does not overlap the semiconductor stack structure 10 in the Z direction. The second electrode 22 is positioned to diametrically oppose the first electrode 21, for example.

The third electrode 23 is electrically connected to the first n-type semiconductor layer 11c. The third electrode 23 is disposed under the semiconductor stack structure 10, for example. In the light emitting element 100, the third electrode 23 is positioned as the lowermost part of the light emitting element 100. In the light emitting element 100, the third electrode 23 is positioned under the semiconductor stack structure 10, the first electrode 21, the second electrode 22, the first wiring 31, the second wiring 32, and the third wiring 33.

The third electrode 23 does not have to be positioned under the semiconductor stack structure 10. For example, the third electrode 23 may be disposed at the same height as that of at least either the first electrode 21 or the second electrode 22, at the same height as that of the semiconductor stack structure 10, or at the same height as that of at least one of the first wiring 31, the second wiring 32, and the third wiring 33.

The first electrode 21 and the second electrode 22 are each made of a metal material, for example. For the metal material, for example, at least one of metals, such as Ti (titanium), Pt (platinum), Rh (rhodium), Au (gold), Ni (nickel), Ta (tantalum), Zr (zirconium), and alloys of these metals can be used. The first electrode 21 and the second electrode 22 can each be a single layer or a multilayer structure in which multiple layers are stacked. The first electrode 21 and the second electrode 22 can each be a multilayer structure in which a Ti layer, a Pt layer, and an Au layer are stacked in that order, for example.

The third electrode 23 is made of at least either a metal material or a semiconductor material, for example. For the metal material, the same metal material as that for the first electrode 21 and the second electrode 22 can be used. For the semiconductor material, for example, Si can be used. The third electrode 23 may be a multilayer structure in which a semiconductor layer is stacked on a metal layer, for example.

The first wiring 31 electrically connects the first electrode 21 and the first p-type semiconductor layer 11a. The first wiring 31 is disposed under the semiconductor stack structure 10 (the first p-type semiconductor layer 11a). In the light emitting element 100, the first wiring 31 extends from the area under the first electrode 21 to the area under the first p-type semiconductor layer 11a. In the light emitting element 100, the first wiring 31 and the first p-type semiconductor layer 11a are electrically connected via the contact electrode 25 positioned between the first wiring 31 and the first p-type semiconductor layer 11a.

The second wiring 32 electrically connects the second electrode 22 and the second n-type semiconductor layer 12c. The second wiring 32 is positioned in the second openings 17. In the light emitting element 100, the second wiring 32 extends from the area under the second electrode 22 to the area under the second n-type semiconductor layer 12c. In the light emitting element 100, the second wiring 32 and the second n-type semiconductor layer 12c are electrically connected by being in contact with one another.

The third wiring 33 electrically connects the third electrode 23 and the first n-type semiconductor layer 11c. The third wiring 33 is positioned in the first openings 16. In the light emitting element 100, the third wiring 33 is disposed under the first n-type semiconductor layer 11c. In the light emitting element 100, the third wiring 33 and the first n-type semiconductor layer 11c are electrically connected by being in contact with one another.

The first wiring 31, the second wiring 32, and the third wiring 33 are each made of a metal material, for example. For the metal material, for example, at least one of metals, such as Au (gold), Pt (platinum), Pd (palladium), Rh (rhodium), Ni (nickel), W (tungsten), Mo (molybdenum), Cr (chromium), Ti (titanium), Al (aluminum), and Cu (copper), and alloys of these metals can be used. The first wiring 31, the second wiring 32, and the third wiring 33 may each be a single layer or a multilayer structure in which multiple layers are stacked. The first wiring 31, the second wiring 32, and the third wiring 33 can each be a multilayer structure in which a Ti layer, an Al—Si—Cu alloy layer, a Ti layer, a Pt layer, an Au layer, and a Ti layer are stacked in that order, for example.

The light emitting element 100 further includes a conducting member 40. The conducting member 40 is disposed between the third wiring 33 and the third electrode 23. The conducting member 40 electrically connects the third wiring 33 and the third electrode 23. A portion 40a of the conducting member 40 is disposed in each of the first openings 16. The portions 40a in the first openings 16 are in contact with the third wiring 33 in the first openings 16. Another portion 40b of the conducting member 40 is disposed in each of the second openings 17, for example. In this case, the light emitting element 100 further includes a first insulation film 45. The first insulation film 45 is disposed between the portions 40b of the conducting member 40 and the second wiring 32. The first insulation film 45 provides insulation between the conducting member 40 and the second wiring 32. For example, the conducting member 40 does not have to be disposed if the third electrode 23 is not under the semiconductor stack structure 10.

The conducting member 40 is made of a metal material, for example. For the metal material, for example, at least one of metals, such as Ni (nickel), Sn (tin), Au (gold), In (indium), and Pb (lead), and alloys of these metals can be used. The conducting member 40 may be a single layer or a multilayer structure in which multiple layers are stacked.

The light emitting element 100 further includes a second insulation film 50. The second insulation film 50 is disposed between the semiconductor stack structure 10 and the first wiring 31, between the semiconductor stack structure 10 and the second wiring 32, and between the semiconductor stack structure 10 and the third wiring 33. Portions of the second insulation film 50 are located between the semiconductor stack structure 10 and the second wiring 32 in the second openings 17. These portions of the second insulation film 50 surround the second wiring 32 in the second openings in a plan view. Other portions of the second insulation film 50 are located between the semiconductor stack structure 10 and the third wiring 33 in the first openings 16. These portions of the second insulation film 50 surround the third wiring 33 in the first openings in a plan view. Furthermore, another portion of the second insulation film 50 is located between the first wiring 31 and the third wiring 33, providing insulation between the first wiring 31 from the third wiring 33. Another portion of the second insulation film 50 is located between the second wiring 32 and the third wiring 33, providing insulation between the second wiring 32 from the third wiring 33.

The second insulation film 50 is made of, for example, an insulating material. For the insulating material, for example, at least either a silicon oxide or silicon nitride can be used.

The light emitting element 100 further includes a surface protective film 55. The surface protective film 55 is disposed on the semiconductor stack structure 10. The surface protective film 55 protects the semiconductor stack structure 10.

The surface protective film 55 is made of an insulating material, for example. For the insulating material, for example, an oxide or nitride containing at least one selected from the group consisting of Si (silicon), Ti (titanium), Zr (zirconium), Nb (niobium), Ta (tantalum), Al (aluminum), and Hf (hafnium) can be used. For the insulating material, for example, at least either a silicon oxide or silicon nitride can be used.

As shown in FIG. 1, in the light emitting element 100, the total area of the second openings 17 is larger than the total area of the first openings 16 in the plan view. The total area of the second openings 17 in the plan view is preferably 1.1 to 2 times the total area of the first openings 16 in the plan view. The total area of the first openings 16 in the plan view is the sum of the areas of all of the first openings 16 in the plan view. The total area of the second openings 17 in the plan view is the sum of the areas of all of the second openings 17 in the plan view.

In the light emitting element 100, the areas of the first openings 16 in the plan view are the same. In the light emitting element 100, the areas of the second openings 17 in the plan view are the same. The areas of the first openings 16 in the plan view may be different from one another. The areas of the second openings 17 in the plan view may be different from one another.

In the light emitting element 100, the area of the third wiring 33 that is in contact with the first n-type semiconductor layer 11c in each of the first openings 16 is smaller than the area of the second wiring 32 that is in contact with the second n-type semiconductor layer 12c in each of the second openings 17, for example.

As shown in FIG. 1, in the plan view, the semiconductor stack structure 10 has a central part 10a and a peripheral part 10b. The central part 10a, for example, includes the center of the semiconductor stack structure 10 in the plan view. The peripheral part 10b surrounds the central part 10a in the plan view. The peripheral part 10b includes the outer edges of the semiconductor stack structure 10 in the plan view. For example, the length from the center of the semiconductor stack structure 10 to the border between the central part 10a and the peripheral part 10b is the same as the length from the outer edge of the semiconductor stack structure 10 to the border between the central part 10a and the peripheral part 10b.

The second openings 17 are positioned, for example, in the region that overlaps the central part 10a in a plan view. The first openings 16 are positioned in the region that overlaps the peripheral part 10b in the plan view. In the light emitting element 100, the first openings 16 are positioned in both the region that overlaps the central part 10a and the region that overlaps the peripheral part 10b, in the plan view. In the light emitting element 100, the second openings 17 are provided in both the region that overlaps the central part 10a and the region that overlaps the peripheral part 10b in the plan view. In the light emitting element 100, the first openings 16 and the second openings 17 are alternately arranged in the X and Y directions. In the light emitting element 100, the first openings 16 are arranged at equal intervals in the X and Y directions, and the second openings 17 are arranged at equal intervals in the X and Y directions.

At least one portion of the upper face of the semiconductor stack structure 10 is roughened, for example. Roughening the upper face of the semiconductor stack structure 10 can improve the upward light extraction efficiency of the semiconductor stack structure 10. The upper face of the semiconductor stack structure 10 is the upper face of the second n-type semiconductor layer 12c.

As shown in FIG. 2, the second n-type semiconductor layer 12c has a first region 12c1 and a second region 12c2. The first regions 12c1 overlap the first openings 16 in a plan view. The second regions 12c2 overlap the second openings 17 in a plan view. The upper face of a first region 12c1 is roughened, for example. The upper face of a second region 12c2 is not roughened, for example. The surface roughness of the upper face of a first region 12c1 is higher than the surface roughness of the upper face of a second region 12c2.

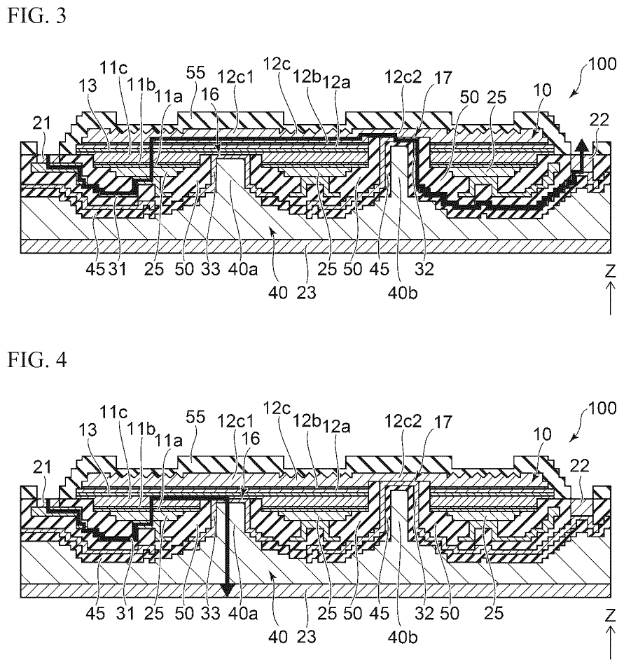

FIG. 3 is a cross-sectional view showing the electric current path in a first emission state of the light emitting element according to the first embodiment.

FIG. 4 is a cross-sectional view showing the electric current path in a second emission state of the light emitting element according to the first embodiment.

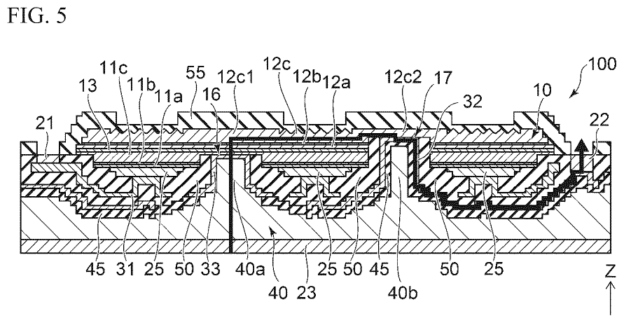

FIG. 5 is a cross-sectional view showing the electric current path in a third emission state of the light emitting element according to the first embodiment.

As shown in FIG. 3 to FIG. 5, the light emitting element 100 has three emission states: first, second, and third emission states.

The first emission state is a state in which both the first active layer 11b and the second active layer 12b emit light. FIG. 3 shows the electric current path in the first emission state. As shown in FIG. 3, in the first emission state, the first electrode 21 functions as the positive electrode, and the second electrode 22 functions as the negative electrode. Specifically, a current flows from the first electrode 21 through the first wiring 31, the contact electrode 25, the first p-type semiconductor 11a, the first active layer 11b, the first n-type semiconductor layer 11c, the intermediate layer 13, the second p-type semiconductor layer 12a, the second active layer 12b, the second n-type semiconductor layer 12c, and the second wiring 32 to the second electrode 22. This allows both the first active layer 11b and the second active layer 12b to emit light.

The second emission state is a state in which the first active layer 11b emits light, but the second active layer 12b does not. FIG. 4 shows the electric current path in the second emission state. As shown in FIG. 4, in the second emission state, the first electrode 21 functions as the positive electrode, and the third electrode 23 functions as the negative electrode. To described in detail, a current flows from the first electrode 21 through the first wiring 31, the contact electrode 25, the first p-type semiconductor layer 11a, the first active layer 11b, the first n-type semiconductor layer 11c, the third wiring 33, and the conducting member 40 (the portions 40a) to the third electrode 23. This allows the first active layer 11b to emit light while not allowing the second active layer 12b to emit light.

The third emission state is a state in which the second active layer 12b emits light, but the first active layer 11b does not. FIG. 5 shows the electric current path in the third emission state. As shown in FIG. 5, in the third emission state, the third electrode 23 functions as the positive electrode, and the second electrode 22 functions as the negative electrode. Specifically, a current flows from the third electrode 23 through the conducting member 40 (the portions 40a), the third wiring 33, the first n-type semiconductor layer 11c, the intermediate layer 13, the second p-type semiconductor layer 12a, the second active layer 12b, the second n-type semiconductor layer 12c, and the second wiring 32 to the second electrode 22. This allows the second active layer 12b to emit light, while not allowing the first active layer 11b to emit light.

As described above, in the light emitting element 100, the emission of the first active layer 11b and the emission of the second active layer 12b can be individually controlled. The first active layer 11b and the second active layer 12b can be alternately used by switching between the active layers for light emission. This can reduce the heat generated by the semiconductor stack structure 10, thereby reducing the shifting of the emission wavelength attributable to the heat generated by the semiconductor stack structure 10. Because the semiconductor stack structure 10 easily generates heat when both the first active layer 11b and the second active layer 12b emit ultraviolet light, for example, it is particularly effective to reduce heat generation by switching between the active layers for light emission. In the case in which the peak wavelength of the light emitted by the first active layer 11b differs from the peak wavelength of the light emitted by the second active layer 12b, switching between the active layers for light emission makes it a wavelength switchable light emitting element.

In the case of allowing the second active layer 12b to emit light as in the first emission state or the third emission state, a high forward voltage V tends to result because there is an intermediate layer 13 in the current path. Accordingly, the total area of the second openings 17 in a plan view is preferably set larger than the total area of the first openings 16 in the plan view. This can increase the area of the second wiring 32 that is in contact with the second n-type semiconductor layer 12c in each of the second openings 17. This, as a result, can lessen the forward voltage VF increase in the first emission state and the third emission state.

Setting the total area of the second openings 17 in a plan view to 1.1 to 2 times the total area of the first openings 16 in the plan view can prevent the difference between the forward voltages VF in the second emission state and the third emission state from becoming excessively large, while reducing the forward voltages VF in the first emission state and the second emission state.

A portion 40a of the conducting member 40 located in each of the first openings 16 can electrically connect the third wiring 33 and the third electrode 23 even in the case in which the third electrode 23 is disposed under the semiconductor stack structure 10. For example, it is possible to employ a design that electrically connects the conducting member 40 and the second n-type semiconductor layer 12c at the second openings 17 as in the case of the second embodiment described later. However, it is preferable to position the portions 40a of the conducting member 40 in the first openings 16 while electrically connecting the third wiring 33 and the first n-type semiconductor layer 11c via the third electrode 23. Specifically, because the first openings 16 are shallower than the second openings 17, they can be easily filled with the conducting member 40. In other words, even if the conducting member 40 is disposed in the first openings 16, voids are barely formed in the first openings 16. This can make it difficult for the forward voltage VF to readily increase.

As shown in FIG. 2, another portion 40b of the conducting member 40 and a first insulation film 45 are preferably positioned in each of the second openings 17. This allows the conducting member 40 to readily dissipate the heat generated by the semiconductor stack structure 10. Interposing the first insulation film 45 between the portions 40b of the conducting member 40 and the second wiring 32 can provide insulation between the portions 40b of the conducting member 40 and the second wiring 32 even in the case in which the portions 40b of the conducting member 40 are disposed in the second openings 17.

In the case of allowing the first active layer 11b and the second active layer 11b to alternately emit light by switching between the two, the first openings 16 become a part of the electric current path in both cases of allowing the first active layer 11b to emit light and allowing the second active layer 12 to emit light. For this reason, as shown in FIG. 1, the first openings 16 are preferably positioned in the region that overlaps the peripheral part 10b of the semiconductor stack structure 10 in the plan view. Arranging the first openings 16 in this manner can easily expand the emission region of the light emitting element 100 to the edges of the semiconductor stack structure 10. It is more preferable to arrange the first openings 16 in the region that overlaps the peripheral part 10b of the semiconductor stack structure 10 while arranging the second openings 17 in the region that overlaps the central part 10a of the semiconductor stack structure 10 in the plan view.

Furthermore, roughening the upper face of the semiconductor stack structure 10 can increase the efficiency in extracting the light from the semiconductor stack structure 10 in the upward direction. On the other hand, roughening the entire upper face of the semiconductor stack structure 10 reduces the thickness of the semiconductor stack structure 10 at certain locations to allow the forward voltage VF to increase. Because the upper ends of the second openings 17 are positioned higher than the upper ends of the first openings 16, the portions of the semiconductor stack structure 10 that overlap the second openings 17 in the plan view tend to be smaller in thickness than the portions of the semiconductor stack structure 10 that overlap the first openings 16 in the plan view. Accordingly, as shown in FIG. 2, it is preferable to roughen the upper face of the second n-type semiconductor layer 12c in the first regions 12c1 that overlap the first openings 16 in the plan view while not roughening the upper face of the second n-type semiconductor layer 12c in the second regions 12c2 that overlap the second openings 17. In other words, the surface roughness of the upper face in the first regions 12c1 is preferably higher than the surface roughness of the upper face in the second regions 12c2. This, as a result, can increase the light extraction efficiency in the first regions 12c1 while lessening the forward voltage VF increase by not reducing the surface to reduce the thickness in the second regions 12c2.

### Variation

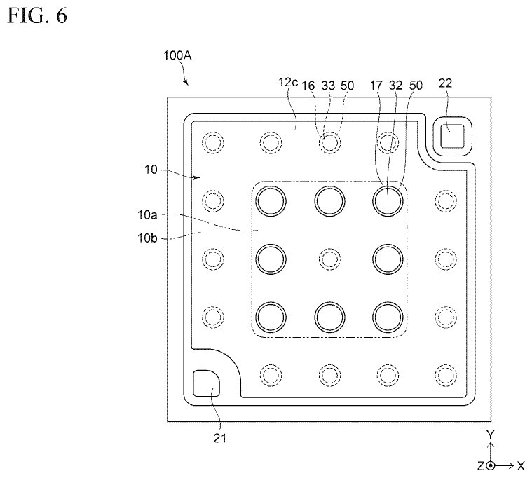

FIG. 6 is a plan view showing a light emitting element in a variation of the first embodiment.

As shown in FIG. 6, the light emitting element 100A in the variation of the first embodiment differs from the light emitting element 100 in terms of the plan view layout of the first openings 16 and the second openings 17. The light emitting element 100A is the same as the light emitting elements 100 in other respects.

In the light emitting element 100A, the second openings 17 are arranged only in the region that overlaps the central part 10a in the plan view. In the light emitting element 100A, the first openings 16 are arranged in the region that overlaps the peripheral part 10b in the plan view. In the light emitting element 100A, the first openings 16 and the second openings 17 are arranged at equal intervals in a matrix. In the light emitting element 100A, one first opening 16 is placed in the center of the region that overlaps the central part 10a, multiple second openings 17 are placed around the first opening 16, and multiple first openings 16 are placed around the second openings 17 in the plan view.

As described above, in the case of allowing the first active layer 11b and the second active layer 12b to alternately emit light by switching between the two, the first openings 16 become a part of the current path in both cases of allowing the first active layer 11b to emit light and allowing the second active layer 12b to emit light. For this reason, as shown in FIG. 6, arranging the first openings 16 in the region that overlaps the peripheral part 10b of the semiconductor stack structure 10 in a plan view while arranging the second openings 17 only in the region that overlaps the central part 10a in the plan view can readily expand the emission region of the light emitting element 100A to the edges of the semiconductor stack structure 10 in both cases of allowing the first active layer 11b to emit light and allowing the second active layer 12b to emit light. Moreover, as shown in FIG. 6, the first openings 16 are preferably arranged in the region that overlaps the central part 10a and is surrounded by the second openings 17 in the plan view. This can reduce the emission distribution nonuniformity in the light emitting element 100A.

### Second Embodiment

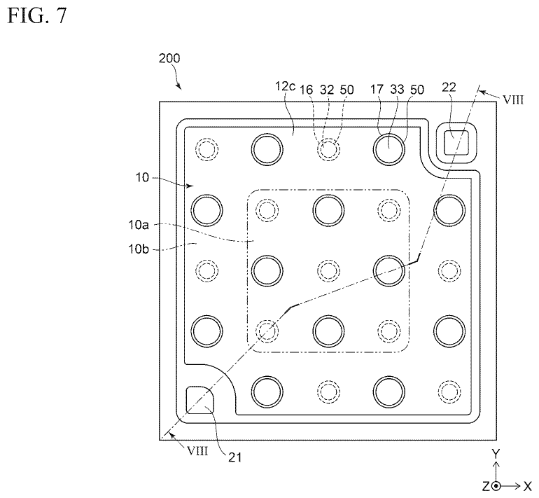

FIG. 7 is a plan view of a light emitting element according to a second embodiment.

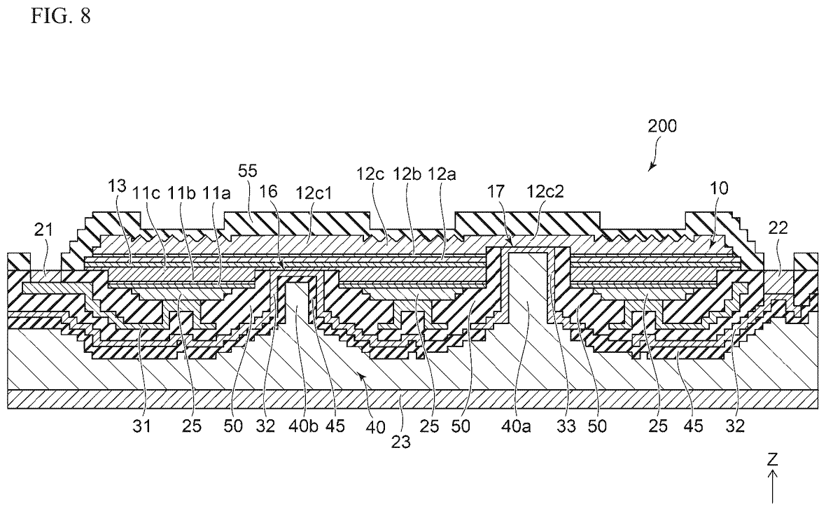

FIG. 8 is a cross-sectional view of the light emitting element according to the second embodiment.

FIG. 8 is a cross section along line VIII-VIII in FIG. 7.

As shown in FIG. 7 and FIG. 8, the light emitting element 200 according to the second embodiment includes a semiconductor stack structure 10, a first electrode 21, a second electrode 22, a third electrode 23, first wiring 31, second wiring 32, and third wiring 33.

In the light emitting element 200, the second electrode 22 is electrically connected to the first n-type semiconductor layer 11c. In the light emitting element 200, the third electrode 23 is electrically connected to the second n-type semiconductor layer 12c. In the light emitting element 200, the second wiring 32 is positioned in the first openings 16. In the light emitting element 200, the second wiring 32 electrically connects the second electrode 22 and the first n-type semiconductor layer 11c. In the light emitting element 200, the second wiring 32 has a portion that is connected to the second electrode 22 and a portion that is connected to the first n-type semiconductor layer 11c. The portion that is connected to the second electrode 22 is connected to the portion that is connected to the first n-type semiconductor layer 11c while bypassing the second openings 17 (the portions 40a of the conducting member 40). In the light emitting element 200, the third wiring 33 is positioned in the second openings 17. In the light emitting element 200, the third wiring 33 electrically connects the third electrode 23 and the second n-type semiconductor layer 12c. The light emitting element 200 is the same as the light emitting element 100 described above in other respects.

In the light emitting element 200, the total area of the second openings 17 in a plan view is, for example, larger than the total area of the first openings 16 in the plan view. The total area of the second openings 17 in a plan view is preferably 1.1 to 2 times the total area of the first openings 16 in the plan view.

The area of the third wiring 33 that is in contact with the second n-type semiconductor layer 12c in each of the second opening 17 is larger than the area of the second wiring 32 that is in contact with the first n-type semiconductor layer 11c in each of the first opening 16, for example.

In the light emitting element 200, the portions 40a of the conducting member 40 are located in the second openings 17. The portions 40a of the conducting member 40 are in contact with the third wiring 33 in the second openings 17. In the light emitting element 200, the portions 40b of the conducting member 40 are positioned in the first openings 16, for example. In this case, the first insulation film 45 is positioned between the portions 40b of the conducting member 40 and the second wiring 32. The first insulation film 45 provides insulation between the portions 40b of the conducting member 40 and the second wiring 32.

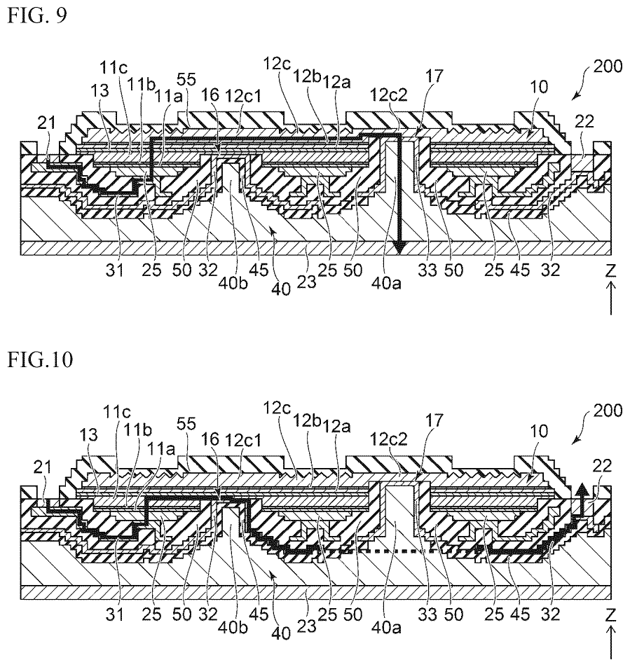

FIG. 9 is a cross-sectional view showing the electric current path in a first emission state of the light emitting element according to the second embodiment.

FIG. 10 is a cross-sectional view of the electric current path in a second emission state of the light emitting element according to the second embodiment.

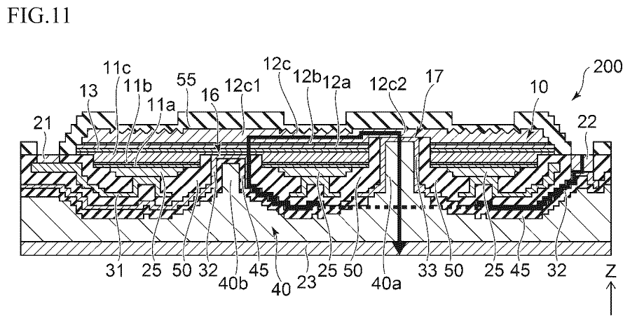

FIG. 11 is a cross-sectional view of the electric current path in a third emission state of the light emitting element according to the second embodiment.

As shown in FIG. 9 to FIG. 11, the light emitting element 200 has three emission states, i.e., the first, second, and third emission states.

The first emission state is a state in which both the first active layer 11b and the second active layer 12b emit light. FIG. 9 shows the electric current path in the first emission state. As shown in FIG. 9, in the first emission state, the first electrode 21 functions as the positive electrode and the third electrode 23 functions as the negative electrode. Specifically, a current flows from the first electrode 21 through the first wiring 31, the contact electrode 25, the first p-type semiconductor layer 11a, the first active layer 11b, the first n-type semiconductor layer 11c, the intermediate layer 13, the second p-type semiconductor layer 12a, the second active layer 12b, the second n-type semiconductor layer 12c, the third wiring 33, and the conducting member 40 (the portions 40a) to the third electrode 23. This allows both the first active layer 11b and the second active layer 12b to emit light.

The second emission state is a state in which the first active layer 11b emits light, but the second active layer 12b does not. FIG. 10 shows the electric current path in the second emission state. As shown in FIG. 10, in the second emission state, the first electrode 21 functions as the positive electrode and the second electrode 22 functions as the negative electrode. Specifically, a current flows from the first electrode 21 through the first wiring 31, the contact electrode 25, the first p-type semiconductor layer 11a, the first active layer 11b, the first n-type semiconductor layer 11c, and the second wiring 32 to the second electrode 22. This allows the first active layer 11b to emit light without allowing the second active layer 12b to emit light. In FIG. 10, the part of the electric current path through the second wiring 32 which is not shown in the cross section along line VIII-VIII is indicated with a broken line.

The third emission state is a state in which the second active layer 12b emits light, but the first active layer 11b does not. FIG. 11 shows the electric current path in the third emission state. As shown in FIG. 11, in the third emission state, the second electrode 22 functions as the positive electrode and the third electrode 23 functions as the negative electrode. Specifically, a current flows from the second electrode 22 through the second wiring 32, the first n-type semiconductor layer 11c, the intermediate layer 13, the second p-type semiconductor layer 12a, the second active layer 12b, the second n-type semiconductor layer 12c, the third wiring 33, and the conducting member 40 (the portions 40a) to the third electrode 23. This allows the second active layer 12b to emit light without allowing the first active layer 11b to emit light. In FIG. 11, the part of the electric current path through the second wiring 32 which is not shown in the cross section along line VIII-VIII is indicated with a broken line.

As described above, in the light emitting element 200, the emission of the first active layer 11b and the emission of the second active layer 12b can be individually controlled. The first active layer 11b and the second active layer 12b can be alternately used by switching between the active layers for light emission. This can reduce the heat generated by the semiconductor stack structure 10, thereby reducing the shifting of the emission wavelength attributable to the heat generated by the semiconductor stack structure 10. Because the semiconductor stack structure 10 easily generates heat when both the first active layer 11b and the second active layer 12b emit ultraviolet light, for example, it is particularly effective in reducing heat generation by switching between the active layers for light emission. In the case in which the peak wavelength of the light emitted by the first active layer 11b differs from the peak wavelength of the light emitted by the second active layer 12b, switching between the active layers for light emission makes it a wavelength switchable light emitting element.

Furthermore, the light emitting element 200 can easily lessen the emission efficiency drop in the case in which the peak wavelength of the light from the first active layer 11b and the peak wavelength of the light from the second active layer 12b are both in the ultraviolet range, but different from one another. Specifically, the drop in the emission efficiency can be easily lessened when both the peak wavelengths of the light from the first active layer 11b and the light from the second active layer 12b are in the ultraviolet range, and the peak wavelength of the light from the second active layer 12b is shorter than the peak wavelength of the light from the first active layer 11b. Specifically, the shorter the wavelength of the light from an active layer, the easier it is for the light to be absorbed by semiconductor layers. Accordingly, in the light emitting element 200, setting the peak wavelength of the light from the second active layer 12b that is closer to the upper face of the semiconductor stack structure 10 (i.e., the light extraction face), shorter than the peak wavelength of the light from the first active layer 11b, can make it difficult for the semiconductor layers to absorb the light from the second active layer 12b. Furthermore, the shorter the wavelength of the light from an active layer, the easier it is for the semiconductor layer to generate heat. In the light emitting element 200, the heat generated by the second active layer 12b can be dissipated easily via the third wiring 33, the conducting member 40, and the third electrode 23. This is because the third wiring 33 and the conducting member 40 each made of a metal material are continuously disposed in the second openings 17. This, as a result, can reduce the wavelength shifting attributable to the heat generated by the second active layer 12b, thereby increasing the emission efficiency.

In the case of allowing the second active layer 12b to emit light as in the first emission state or the third emission state, a high forward voltage V tends to result because there is an intermediate layer 13 in the current path. Accordingly, the total area of the second openings 17 in a plan view is preferably set larger than the total area of the first openings 16 in the plan view. This can increase the area of the third wiring 33 that is in contact with the second n-type semiconductor layer 12c in each of the second openings 17. This, as a result, can lessen the forward voltage VF increase in the first emission state and the third emission state.

Setting the total area of the second openings 17 in a plan view to 1.1 to 2 times the total area of the first openings 16 in the plan view can prevent the difference between the forward voltages VF in the second emission state and the third emission state from becoming excessively large, while reducing the forward voltage VF.

As shown in FIG. 8, moreover, a portion 40a of the conducting member 40 located in each of the second opening 17 can electrically connect the third wiring 33 and the third electrode 23 even in the case in which the third electrode 23 is disposed under the semiconductor stack structure 10.

Furthermore, another portion 40b of the conducting member 40 and a first insulation film 45 are preferably located in each of the first openings 16. This can make it easier to dissipate the heat generated by the semiconductor stack structure 10 via the conducting member 40. Interposing the first insulation film 45 between the portion 40b of the conducting member 40 and the second wiring 32 can provide insulation between the portion 40b of the conducting member 40 and the second wiring 32 even in the case in which the portion 40b of the conducting member 40 is disposed in each of the first openings 16.

In the case of allowing the first active layer 11b and the second active layer 11b to alternately emit light by switching between the two, the first openings 16 become a part of the electric current path in both cases of allowing the first active layer 11b to emit light and allowing the second active layer 12 to emit light. For this reason, as shown in FIG. 7, the first openings 16 are preferably positioned in the region that overlaps the peripheral part 10b of the semiconductor stack structure 10 in the plan view. Arranging the first openings 16 in this manner can easily expand the emission region of the light emitting element 200 to the edges of the semiconductor stack structure 10. It is more preferable to arrange the first openings 16 in the region that overlaps the peripheral part 10b of the semiconductor stack structure 10 while arranging the second openings 17 in the region that overlaps the central part 10a of the semiconductor stack structure 10 in the plan view is more preferable.

In the second embodiment, moreover, it is similarly preferable to roughen the upper face of the second n-type semiconductor layer 12c in the first regions 12c1 that overlap the first openings 16 in the plan view while not roughening the upper face of the second n-type semiconductor layer 12c in the second regions 12c2 that overlap the second openings 17. In other words, the surface roughness of the upper face in the first regions 12c1 is preferably higher than the surface roughness of the upper face in the second regions 12c2. This, as a result, can increase the light extraction efficiency in the first regions 12c1 while lessening the forward voltage VF increase by not roughening the surface to reduce the thickness in the second regions 12c2.

### Variation

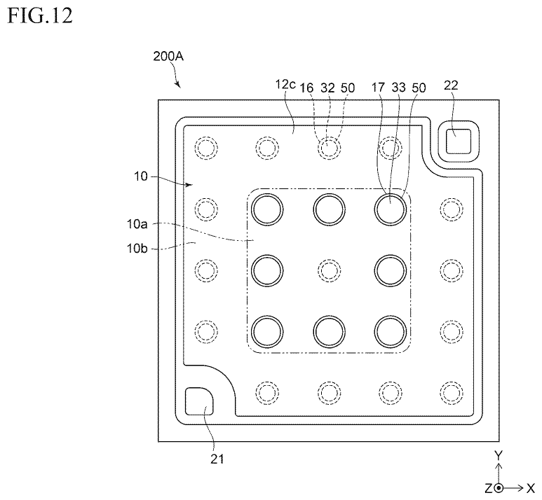

FIG. 12 is a plan view showing a light emitting element in a variation of the second embodiment.

As shown in FIG. 12, the light emitting element 200A in the variation of the second embodiment differs from the light emitting element 200 in terms of the plan view layout of the first openings 16 and the second openings 17. The light emitting element 200A is the same as the light emitting elements 200 in other respects.

In the light emitting element 200A, the second openings 17 are arranged only in the region that overlaps the central part 10a in the plan view. In the light emitting element 200A, the first openings 16 are arranged in the region that overlaps the peripheral part 10b in the plan view. In the light emitting element 200A, the first openings 16 and the second openings 17 are arranged at equal intervals in a matrix. In the light emitting element 200A, one first opening 16 is placed in the center of the region that overlaps the central part 10a, multiple second openings 17 are placed around the first opening 16, and multiple first openings 16 are placed around the second openings 17 in the plan view.

As described above, in the case of allowing the first active layer 11b and the second active layer 12b to alternately emit light by switching between the two, the first openings 16 become a part of the current path in both cases of allowing the first active layer 11b to emit light and allowing the second active layer 12b to emit light. For this reason, as shown in FIG. 12, arranging the first openings 16 in the region that overlaps the peripheral part 10b of the semiconductor stack structure 10 in a plan view while arranging the second openings 17 only in the region that overlaps the central part 10a in the plan view can readily expand the emission region of the light emitting element 200A to the edges of the semiconductor stack structure 10 in both cases of allowing the first active layer 11b to emit light and allowing the second active layer 12b to emit light. Moreover, as shown in FIG. 12, the first openings 16 are preferably arranged in the region that overlaps the central part 10a and is surrounded by the second openings 17 in the plan view. This can reduce the emission distribution nonuniformity in the light emitting element 200A.

As described above, an embodiment of the present disclosure can provide a light emitting element in which the emission of the first active layer and the second active layer can be individually controlled.

The embodiments described above are examples that give shape to the present invention, but the present invention is not limited to these embodiments. For example, embodiments obtained by adding to, removing from, or changing a constituent or process of any of the embodiments described above are also encompassed by the present invention. Furthermore, the embodiments described above can be implemented in combination with one another.

1. A light emitting element comprising:
a semiconductor stack structure comprising:
a first p-type semiconductor layer,
a first active layer disposed on the first p-type semiconductor layer,
a first n-type semiconductor layer disposed on the first active layer,
an intermediate layer disposed on the first n-type semiconductor layer,
a second p-type semiconductor layer disposed on the intermediate layer,
a second active layer disposed on the second p-type semiconductor layer, and
a second n-type semiconductor layer disposed on the second active layer, wherein:
a plurality of first openings are continuously located in the first p-type semiconductor layer, the first active layer, and the first n-type semiconductor layer, and
a plurality of second openings are continuously located in the first p-type semiconductor layer, the first active layer, the first n-type semiconductor layer, the intermediate layer, the second p-type semiconductor layer, the second active layer, and the second n-type semiconductor layer;
a first electrode positioned apart from the semiconductor stack structure in a plan view and electrically connected to the first p-type semiconductor layer;
a second electrode electrically connected to the second n-type semiconductor layer;
a third electrode electrically connected to the first n-type semiconductor layer;
a first wiring disposed under the semiconductor stack structure and electrically connecting the first electrode and the first p-type semiconductor layer;
a second wiring positioned in the second openings and electrically connecting the second electrode and the second n-type semiconductor layer; and
a third wiring positioned in the first openings and electrically connecting the third electrode and the first n-type semiconductor layer.

2. The light emitting element according to claim 1, wherein a total area of the second openings in a plan view is larger than a total area of the first openings.

3. The light emitting element according to claim 2, wherein the total area of the second openings in a plan view is 1.1 to 2 times the total area of the first openings in the plan view.

4. The light emitting element according to claim 2, wherein:
the semiconductor stack structure comprises a central part and a peripheral part that surrounds the central part in a plan view;
the second openings are positioned in the region that overlaps the central part in the plan view; and
the first openings are positioned in the region that overlaps the peripheral part in the plan view.

5. The light emitting element according to claim 1, further comprising a conducting member disposed between the third wiring and the third electrode and electrically connecting the third wiring and the third electrode, a portion of the conducting member being positioned in each of the first openings.

6. The light emitting element according to claim 5, wherein:
another portion of the conducting member is disposed in each of the second openings, and
the light emitting element further comprises an insulation film disposed between said portions of the conducting member and the second wiring.

7. The light emitting element according to claim 6, wherein:
the semiconductor stack structure comprises a central part, and a peripheral part that surrounds the central part in a plan view;
the second openings are positioned in the region that overlaps the central part in the plan view; and
the first openings are positioned in the region that overlaps the peripheral part in the plan view.

8. The light emitting element according to claim 1, wherein:
the semiconductor stack structure comprises a central part, and a peripheral part that surrounds the central part in a plan view;
the second openings are positioned in the region that overlaps the central part in the plan view; and
the first openings are positioned in the region that overlaps the peripheral part in the plan view.

9. The light emitting element according to claim 8, wherein the second openings are positioned only in the region that overlaps the central part in a plan view.

10. The light emitting element according to claim 1, wherein the second n-type semiconductor layer comprises first regions that overlap the first openings and second regions that overlap the second openings in a plan view, the surface roughness of the upper face thereof in the first regions being higher than the surface roughness of the upper face in the second regions.

11. A light emitting element comprising:
a semiconductor stack structure comprising:
a first p-type semiconductor layer,
a first active layer disposed on the first p-type semiconductor layer,
a first n-type semiconductor layer disposed on the first active layer,
an intermediate layer disposed on the first n-type semiconductor layer,
a second p-type semiconductor layer disposed on the intermediate layer,
a second active layer disposed on the second p-type semiconductor layer, and
a second n-type semiconductor layer disposed on the second active layer, wherein:
a plurality of first openings are continuously located in the first p-type semiconductor layer, the first active layer, and the first n-type semiconductor layer, and
a plurality of second openings are continuously located in the first p-type semiconductor layer, the first active layer, the first n-type semiconductor layer, the intermediate layer, the second p-type semiconductor layer, the second active layer, and the second n-type semiconductor layer;
a first electrode disposed apart from the semiconductor stack structure in a plan view and electrically connected to the first p-type semiconductor layer;
a second electrode electrically connected to the first n-type semiconductor layer;
a third electrode electrically connected to the second n-type semiconductor layer;
a first wiring disposed under the semiconductor stack structure and electrically connecting the first electrode and the first p-type semiconductor layer;
a second wiring positioned in the first openings and electrically connecting the second electrode and the first n-type semiconductor layer; and
a third wiring positioned in the second openings and electrically connecting the third electrode and the second n-type semiconductor layer.

12. The light emitting element according to claim 11, wherein a total area of the second openings in a plan view is larger than a total area of the first openings.

13. The light emitting element according to claim 12, wherein the total area of the second openings in a plan view is 1.1 to 2 times the total area of the first openings in the plan view.

14. The light emitting element according to claim 12, wherein:
the semiconductor stack structure comprises a central part, and a peripheral part that surrounds the central part in a plan view;
the second openings are positioned in the region that overlaps the central part in the plan view; and
the first openings are positioned in the region that overlaps the peripheral part in the plan view.

15. The light emitting element according to claim 11, further comprising a conducting member disposed between the third wiring and the third electrode and electrically connecting the third wiring and the third electrode, a portion of the conducting member being positioned in each of the second openings.

16. The light emitting element according to claim 15, wherein:
another portion of the conducting member is disposed in each of the first openings, and
the light emitting element further comprises an insulation film disposed between said portions of the conducting member and the second wiring.

17. The light emitting element according to claim 11, wherein:
the semiconductor stack structure comprises a central part, and a peripheral part that surrounds the central part in a plan view;
the second openings are positioned in the region that overlaps the central part in the plan view; and
the first openings are positioned in the region that overlaps the peripheral part in the plan view.

18. The light emitting element according to claim 17, wherein the second openings are positioned only in the region that overlaps the central part in a plan view.
